(19) United States
(12) Patent Application Publication
(10) Pub. No.: US 2025/0089518 A1
(43) Pub. Date: Mar. 13, 2025

(54) DISPLAY PANEL, MANUFACTURING METHOD THEREOF, AND DISPLAY APPARATUS

(71) Applicant: BOE TECHNOLOGY GROUP CO., LTD., Beijing (CN)

(72) Inventors: Haidong WU, Beijing (CN); Yansong LI, Beijing (CN); Mingli LIU, Beijing (CN); Xiaobo DU, Beijing (CN); Hongli WANG, Beijing (CN)

(21) Appl. No.: 18/288,444

(22) PCT Filed: Feb. 9, 2023
(86) PCT No.: PCT/CN2023/075132

§ 371 Date: Oct. 26, 2023

(51) Int. Cl. H10K 59/80; H10K 50/115; H10K 59/12; H10K 59/122; H10K 102/00

(52) U.S. Cl. CPC H10K 59/80522; H10K 50/115; H10K 59/1201; H10K 59/122; H10K 59/873; H10K 59/879; H10K 2102/3026

(57) ABSTRACT

A display panel, including: a substrate; a pixel defining layer; a plurality of light-emitting devices each including a light-emitting functional layer and first and second electrodes; a supplementary electrode on a side of the second electrode away from the substrate, where an orthographic projection of the supplementary electrode on the substrate covers orthographic projections of light-emitting functional layers and/or second electrodes and/or first electrodes of the light-emitting devices of certain colors on the substrate; a supplementary electrode mutual repulsion layer on a side of the second electrode away from the substrate, where an orthographic projection of the supplementary electrode mutual repulsion layer on the substrate is complementary in pattern with the orthographic projection of the supplementary electrode on the substrate; and an encapsulation layer on a side of the supplementary electrode and the supplementary electrode mutual repulsion layer away from the substrate, and configured to encapsulate the light-emitting devices.

### TECHNICAL FIELD

Embodiments of the present disclosure relate to the field of display technology, and in particular, to a display panel, a manufacturing method thereof, and a display apparatus.

### BACKGROUND

Currently, electroluminescent display products are becoming more and more important in the display industry. Especially, organic light-emitting diodes (OLEDs) have been widely popularized and applied in display in recent years due to their advantages of high color gamut, flexibility, fast response, and the like. In addition, in recent years, quantum dot light-emitting diodes (QLEDs) have gained attention of many companies and researchers due to their advantages of low manufacturing cost, high color gamut, and the like.

### SUMMARY

In a first aspect, an embodiment of the present disclosure provides a display panel, including: a substrate;

a plurality of light-emitting devices of different colors on the substrate; wherein each of the plurality of light-emitting devices includes a first electrode, a light-emitting functional layer and a second electrode sequentially superimposed away from the substrate;

a supplementary electrode on a side of the second electrode away from the substrate, wherein an orthographic projection of the supplementary electrode on the substrate covers orthographic projections of light-emitting functional layers and/or second electrodes and/or first electrodes of the light-emitting devices of certain colors on the substrate;

a supplementary electrode mutual repulsion layer on a side of the second electrode away from the substrate, wherein an orthographic projection of the supplementary electrode mutual repulsion layer on the substrate is complementary in pattern with the orthographic projection of the supplementary electrode on the substrate; and
an encapsulation layer on a side of the supplementary electrode and the supplementary electrode mutual repulsion layer away from the substrate, and configured to encapsulate the light-emitting devices.

In some embodiments, the plurality of light-emitting devices include red, green, and blue light-emitting devices,
the supplementary electrode is in contact with and connected to the second electrode; and
the supplementary electrode mutual repulsion layer is in contact with the second electrode.

In some embodiments, the supplementary electrode is located on the second electrode of the red light-emitting device; and
the supplementary electrode mutual repulsion layer is located on the second electrodes of the green and blue light-emitting devices.

In some embodiments, the supplementary electrode is located on the second electrode of the green light-emitting device; and
the supplementary electrode mutual repulsion layer is located on the second electrodes of the red and blue light-emitting devices.

In some embodiments, the supplementary electrode is located on the second electrode of the blue light-emitting device; and
the supplementary electrode mutual repulsion layer is located on the second electrodes of the red and green light-emitting devices.

In some embodiments, the supplementary electrode is located on the second electrodes of the red and green light-emitting devices; and
the supplementary electrode mutual repulsion layer is located on the second electrode of the blue light-emitting device.

In some embodiments, the supplementary electrode is located on the second electrodes of the blue and green light-emitting devices; and
the supplementary electrode mutual repulsion layer is located on the second electrode of the red light-emitting device.

In some embodiments, the supplementary electrode is located on the second electrodes of the blue and red light-emitting devices; and
the supplementary electrode mutual repulsion layer is located on the second electrode of the green light-emitting device.

In some embodiments, the second electrode is made of a light-transmitting metal material; and
the supplementary electrode is made of a metal material including any one of Mg, Ag, Al, Li, K and Ca, or a metal alloy material including any one of MgₓAg₍₁₋ₓ₎, LiₓAl₍₁₋ₓ₎, LiₓCa₍₁₋ₓ₎ and LiₓAg₍₁₋ₓ₎.

In some embodiments, the second electrode has a thickness ranging from 1 nm to 20 nm; and
the supplementary electrode has a thickness ranging from 1 nm to 10 nm.

In some embodiments, the supplementary electrode mutual repulsion layer is made of an amine, diamine, or triamine based material.

In some embodiments, the supplementary electrode mutual repulsion layer is made of any one of —N,N′-diphenyl-N,N′-bis(9-phenyl-9H-carbazol-3-yl)biphenyl-4,4′-diamine; N-(biphenyl-4-yl)-9,9-dimethyl-N-(4-(9-phenyl-9H-carbazol-3-yl)phenyl)-9H-fluoren-2-amine; 4,4′,4″-tris(3-methylphenylphenylamino)triphenylamine; N,N′-bis(1-naphthyl)-N,N′-diphenyl[1,1′-biphenyl]-4,4′-diamine, or 4,4′-bis[N-(3-methylphenyl)-N-phenylamino]biphenyl; or N4,N4′-diphenyl-N4,N4′-bis(9-phenyl-9H-carbazol-3-yl)diphenyl-4,4′-diamine′N(diphe nyl-4-yl) 9,9-dimethyl-N-(4 (9-phenyl-9H-carbazol-3-yl)phenyl)-9H-fluoren-2-amine.

In some embodiments, the display panel further includes a light extraction layer on a side of the supplementary electrode and the supplementary electrode mutual repulsion layer away from the substrate, and on a side of the encapsulation layer close to the substrate; wherein
an orthographic projection of the light extraction layer on the substrate covers orthographic projections of at least the plurality of light-emitting devices on the substrate.

In some embodiments, the light extraction layer has a refractive index of 1.8 or more at a wavelength of 530 nm, and an extinction coefficient of 0.01 or less at a wavelength of 450 nm to 780 nm.

In some embodiments, the light extraction layer is made of a material including any one of N,N′-bis(1-naphthyl)-N,N′-diphenyl-1,1′-biphenyl-4-4′-diamine; a triphenyldiamine derivative; N,N′-diphenyl-N,N′-bis(4′-(N,N-bis(1-naphthyl)-amido)-4-biphenyl)-benzidine; 1,3,5-tris(N-3-methylphenyl-N-phenylamino)benzene; or copper phthalocyanine.

In some embodiments, the light extraction layer has a thickness ranging from 60 nm to 100 nm.

In some embodiments, the display panel further includes a pixel defining layer on the substrate, wherein a plurality of openings are formed in the pixel defining layer;
each of the plurality of light-emitting devices includes a portion in a corresponding one of the plurality of openings;
a side surface of the pixel defining layer, formed between two adjacent ones of the plurality of openings and away from the substrate, forms an arc surface that protrudes towards a side away from the substrate; and
the two adjacent light-emitting devices have different colors.

In some embodiments, light-emitting functional layers of the two adjacent light-emitting devices extend onto the arc surface and meet each other; and second electrodes of the two adjacent light-emitting devices extend onto the arc surface, and meet each other or are spaced apart from each other.

In some embodiments, light-emitting functional layers of the two adjacent light-emitting devices extend onto the arc surface and are arranged in a lapped manner.

In some embodiments, a lapped area of the light-emitting functional layers has a cross section perpendicular to the substrate with a length A,
each opening has a cross section perpendicular to the substrate with a length B; where
A/B is less than 5%;
the cross section of the lapped area of the light-emitting functional layers perpendicular to the substrate is parallel to the cross section of the opening perpendicular to the substrate; and
the length of the cross section of the lapped area of the light-emitting functional layers perpendicular to the substrate, and the length of the cross section of the opening perpendicular to the substrate, are parallel to the substrate.

In some embodiments, second electrodes of the two adjacent light-emitting devices extend onto the arc surface and are arranged in a lapped manner.

In some embodiments, a lapped area of the second electrodes has a cross section perpendicular to the substrate with a length C, where
C/B is less than 5%;
the cross section of the lapped area of the second electrodes perpendicular to the substrate is parallel to the cross section of the opening perpendicular to the substrate; and
the length of the cross section of the lapped area of the second electrodes perpendicular to the substrate, and the length of the cross section of the opening perpendicular to the substrate, are parallel to the substrate.

In some embodiments, C≠A.

In some embodiments, C>A.

In some embodiments, the display panel further includes a pixel defining layer on the substrate, wherein a plurality of openings are formed in the pixel defining layer;
an orthographic projection of each of the plurality of light-emitting device on the substrate is within an orthographic projection of a corresponding one of the plurality of openings on the substrate.

In some embodiments, the light-emitting functional layer includes a hole injection layer, a hole transport layer, an electron blocking layer, a light-emitting layer, a hole blocking layer, an electron transport layer and an electron injection layer,
the hole injection layer, the hole transport layer, the electron blocking layer, the light-emitting layer, the hole blocking layer, the electron transport layer and the electron injection layer are sequentially superimposed along a direction away from the substrate; and
the light-emitting layer is made of an organic electroluminescent material or a quantum dot light-emitting material.

An embodiment of the present disclosure further provides a display apparatus, including the display panel as described above.

An embodiment of the present disclosure further provides a method of manufacturing a display panel, including:
preparing a substrate;
preparing a first electrode of a light-emitting device on the substrate;
preparing a pixel defining layer and openings therein on the substrate after the above steps are completed;
sequentially preparing a light-emitting functional layer and a second electrode on the substrate after the above steps are completed;
preparing a supplementary electrode mutual repulsion layer on the substrate after the above steps are completed;
preparing a supplementary electrode on the substrate after the above steps are completed; and
preparing an encapsulation layer on the substrate after the above steps are completed.

In some embodiments, the supplementary electrode mutual repulsion layer is prepared by an evaporation, printing or sputtering process; and the supplementary electrode is prepared by an evaporation process.

In some embodiments, after preparing the supplementary electrode and before preparing the encapsulation layer: a light extraction layer is prepared by evaporation, printing or sputtering.

### BRIEF DESCRIPTION OF DRAWINGS

The accompanying drawings, which are included to provide a further understanding of the present disclosure and constitute a part of this specification, serve to explain the present disclosure together with the following detailed description, but do not constitute a limitation of the present disclosure. The above and other features and advantages will become more apparent to one of ordinary skill in the art by describing detailed examples with reference to the accompanying drawings, in which:

FIG. 1a is a schematic structural top view of a display panel according to an embodiment of the present disclosure.

FIG. 1b is a structural cross-sectional view taken along line AA′ of FIG. 1a.

FIG. 1c is another structural cross-sectional view taken along line AA′ of FIG. 1a.

FIG. 1d is yet another structural cross-sectional view taken along line AA′ of FIG. 1a.

FIG. 1e is yet another structural cross-sectional view taken along line AA′ of FIG. 1a.

FIG. 1f is yet another structural cross-sectional view taken along line AA′ of FIG. 1a.

FIG. 1g is yet another structural cross-sectional view taken along line AA′ of FIG. 1a.

FIG. 2 is a graph of luminance decay with the view angle of red, green and blue light-emitting devices in a display panel with no supplementary electrode.

FIG. 3 is a graph of luminance decay with the view angle of red, green and blue light-emitting devices in the display panel of FIG. 1b.

FIG. 4 is another graph of luminance decay with the view angle of red, green and blue light-emitting devices in a display panel with no supplementary electrode.

FIG. 5 is a graph of luminance decay with the view angle of red, green and blue light-emitting devices in the display panel of FIG. 1e.

FIG. 6 is yet another structural cross-sectional view taken along line AA′ of FIG. 1a.

FIG. 7 is yet another structural cross-sectional view taken along line AA′ of FIG. 1a.

### DETAIL DESCRIPTION OF EMBODIMENTS

In order to enable one of ordinary skill in the art to better understand the technical solutions of the embodiments of the present disclosure, a display panel, a manufacturing method thereof, and a display apparatus provided in the embodiments of the present disclosure are further described in detail below with reference to the accompanying drawings and the detailed description.

The embodiments of the present disclosure will be described more fully hereinafter with reference to the accompanying drawings, and may be embodied in different forms and should not be construed as limited to the embodiments set forth herein. Rather, these embodiments are provided so that this disclosure will be thorough and complete, and will fully convey the scope of the present disclosure to one of ordinary skill in the art.

The embodiments of the present disclosure are not limited to the embodiments shown in the drawings, but include modifications of configurations formed based on a manufacturing process. Thus, the regions illustrated in the figures have schematic properties, and the shapes of the regions shown in the figures illustrate specific shapes of regions, but are not intended to be limiting.

A top emitting electroluminescent display product includes red, green and blue light-emitting devices, each of which includes an anode, a light-emitting functional layer and a cathode sequentially arranged in a superimposed manner. The light-emitting functional layer includes a hole injection layer, a hole transport layer, an electron blocking layer, a light-emitting layer, a hole blocking layer, an electron transport layer, and an electron injection layer sequentially arranged on the anode in a superimposed manner. The cathodes of different colors of light-emitting devices typically adopt a metal or alloy (such as magnesium-silver alloy) with a low work function, which material can reduce an energy level difference between the cathodes and the electron transport layer in the light-emitting functional layer, and thus increase the light-emitting efficiency of the light-emitting devices. The cathodes of different colors of light-emitting devices have a same thickness. However, the red, green and blue light-emitting devices have different magnitudes of luminance decay with the view angle, resulting in severe angular color shift in the top emitting electroluminescent display product.

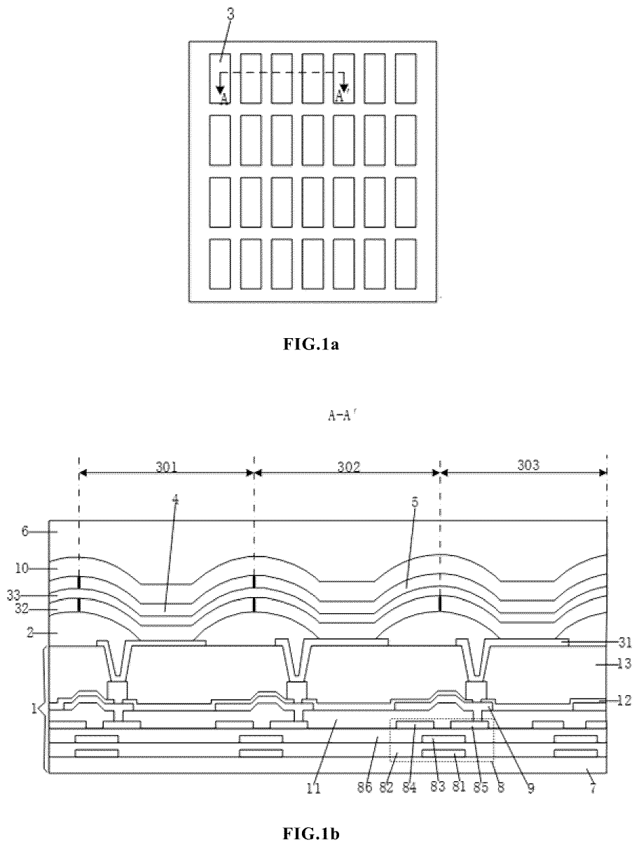

In order to solve the above problem in the existing art, in a first aspect, an embodiment of the present disclosure provides a display panel. Referring to FIG. 1a, a schematic structural top view of a display panel according to an embodiment of the present disclosure is shown. FIG. 1b is a structural cross-sectional view taken along line AA′ of FIG. 1a. As shown, the display panel includes a substrate 1, and a plurality of light-emitting devices 3 of different colors on the substrate 1. Each of the light-emitting devices 3 includes a first electrode 31, a light-emitting functional layer 32 and a second electrode 33 sequentially arranged away from the substrate 1 in a superimposed manner. The display panel further includes: a supplementary electrode 4 on a side of the second electrode 33 away from the substrate 1, where an orthographic projection of the supplementary electrode 4 on the substrate 1 covers orthographic projections of light-emitting functional layers 32 of the light-emitting devices 3 of certain colors on the substrate 1; a supplementary electrode mutual repulsion layer 5 on a side of the second electrode 33 away from the substrate 1, where an orthographic projection of the supplementary electrode mutual repulsion layer 5 on the substrate 1 is complementary in pattern with the orthographic projection of the supplementary electrode 4 on the substrate 1; and an encapsulation layer 6 on a side of the supplementary electrode 4 and the supplementary electrode mutual repulsion layer 5 away from the substrate 1, and configured to encapsulate the light-emitting devices 3.

The supplementary electrode 4 can be deposited only in an area without the supplementary electrode mutual repulsion layer 5, so that preparation of the supplementary electrode 4 can be realized through preparation of the supplementary electrode mutual repulsion layer 5. Each light-emitting device 3 is a top emitting device. An optical resonant cavity (i.e., a microcavity) is formed between a side surface of the first electrode 31 of the light-emitting device 3 away from the substrate 1 and a side surface of the second electrode 33 close to the substrate 1.

In this embodiment, the thicker the second electrode 33 is, the stronger the microcavity effect of the light-emitting device 3 is, the principle of which lies in that: a thicker second electrode 33 has a higher reflectivity to light, and according to the calculation formula of microcavity effect, the higher the reflectivity of the second electrode 33 to light is, the stronger the microcavity effect is. An orthographic projection of the light-emitting functional layer 32 on the substrate 1 covers an orthographic projection of an effective light-emitting area of the light-emitting device 3 on the substrate 1. With the orthographic projection of the supplementary electrode 4 on the substrate 1 covering orthographic projections of light-emitting functional layers 32 of the light-emitting devices 3 of certain colors on the substrate 1, the second electrodes 33 of different colors of light-emitting devices 3 differ in thickness, so that the optical resonant cavities (microcavities) formed between the first electrodes 31 and the second electrodes 33 of different colors of light-emitting devices 3 also differ. The thicker the second electrode 33 is, the stronger the microcavity effect of the light-emitting device 3 is, and the faster the luminance of the light-emitting device 3 decays with changes of the view angle. The luminance decay curve of a single color of light-emitting device 3 is optimized by means of different strengths of the microcavity effect, so that the luminance decay curves of different colors of light-emitting devices 3 tend to be the same, and thus the angular color shift of the display panel is improved.

In some embodiments, the display panel further includes a pixel defining layer 2 on the substrate 1, in which a plurality of openings are formed; and each of the light-emitting devices 3 includes a portion in a corresponding opening.

In some embodiments, the display panel further includes a pixel defining layer on the substrate, in which a plurality of openings are formed; and an orthographic projection of each light-emitting device on the substrate is within an orthographic projection of a corresponding opening (not shown) on the substrate.

In some embodiments, the substrate 1 includes a base 7, and a pixel driving circuit on the base 7. The pixel driving circuit may be any driving circuit, such as 3 transistors and 1 capacitor (3T1C) circuit, 5 transistors and 1 capacitor (5T1C) circuit, 7 transistors and 1 capacitor (7T1C) circuit, or 9 transistors and 1 capacitor (9T1C) circuit. FIG. 1b shows a drive transistor 8 in the pixel driving circuit. The drive transistor 8 includes a gate 81, a gate insulating layer 82, an active layer 83, a source 84 and a drain 85. An intermediate dielectric layer 86 is provided between the active layer 83 and the source 84 as well as the drain 85, and the source 84 and the drain 85 are connected to the active layer 83 through vias in the intermediate dielectric layer 86. The drain 85 of the drive transistor 8 is connected to the first electrode 31 of the light-emitting device 3 via a conductive structure 9 on a side of the pixel driving circuit away from the base 7. A first insulating layer 11 is disposed between the drain 85 and the conductive structure 9. A second insulating layer 12 and a planarization layer 13 are disposed between the conductive structure 9 and the first electrode 31. The second insulating layer 12 and the planarization layer 13 are sequentially superimposed on a side of the conductive structure 9 away from the base 7. The conductive structure 9 and the first electrode 31 are mutually connected through vias in the second insulating layer 12 and the planarization layer 13.

In some embodiments, the light-emitting devices 3 include red, green, and blue light-emitting devices, and the supplementary electrode 4 is in contact with and connected to the second electrode 33; and the supplementary electrode mutual repulsion layer 5 is in contact with the second electrode 33. In this embodiment, the second electrodes 33 of the plurality of light-emitting devices 3 of different colors are integrally connected. The supplementary electrode 4 may increase the thickness of the second electrodes 33 of a certain color or certain colors of light-emitting devices 3, so that the microcavity effect of the certain color or certain colors of light-emitting devices 3 becomes stronger, and the faster the luminance of the certain color or certain colors of light-emitting devices 3 decays with changes of the view angle.

In some embodiments, referring to FIG. 1b, the supplementary electrode 4 is located on the second electrode 33 of the red light-emitting device 301; and the supplementary electrode mutual repulsion layer 5 is located on the second electrodes 33 of the green and blue light-emitting devices 302, 303.

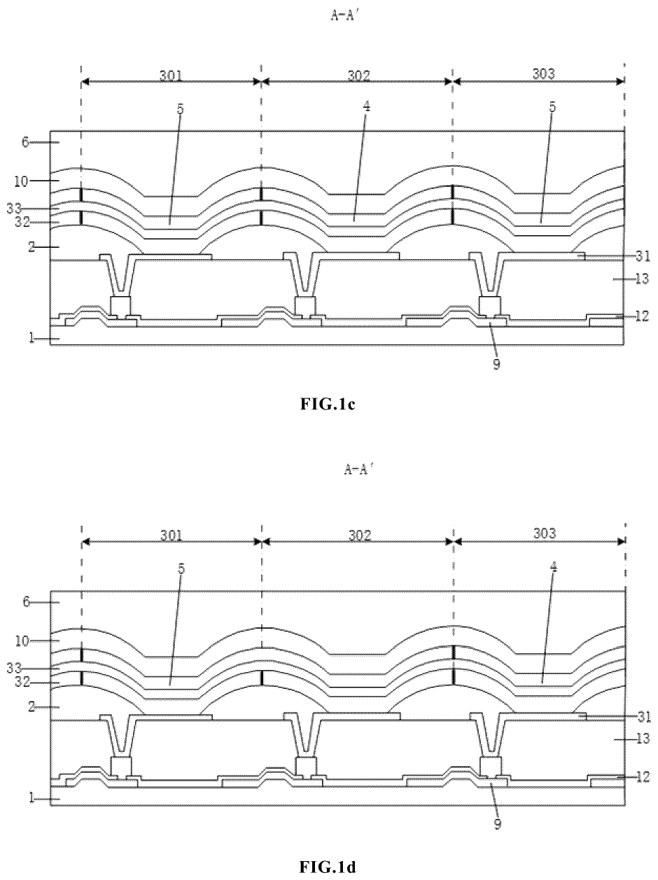

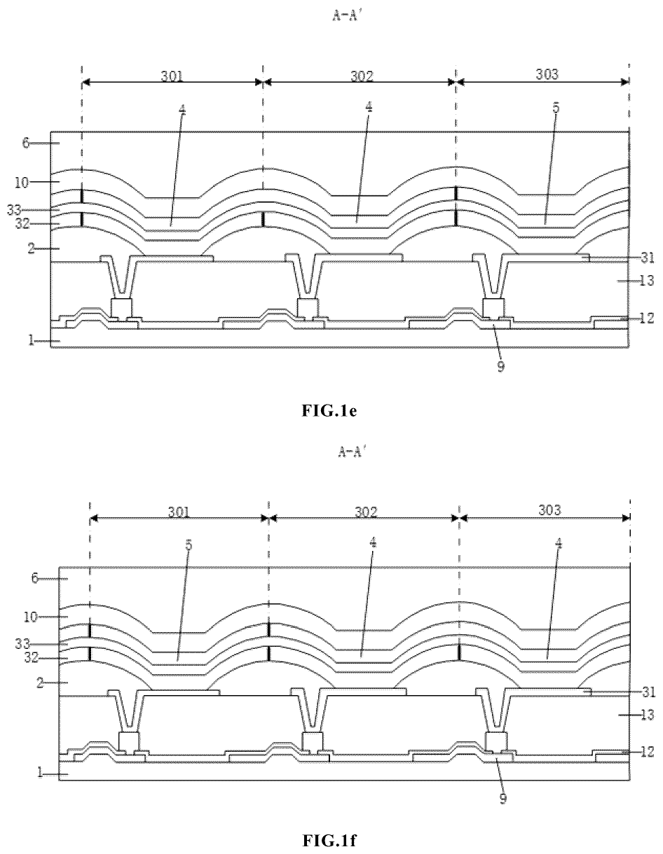

In some embodiments, referring to FIG. 2, a graph of luminance decay with the view angle of red, green and blue light-emitting devices in a display panel with no supplementary electrode is shown. As can be seen in the figure, the luminance decay with the view angle of the red light-emitting device 301 is slower than that of the green light-emitting device 302 and the blue light-emitting device 303. Referring to FIG. 3, a graph of luminance decay with the view angle of red, green and blue light-emitting devices in the display panel of FIG. 1b is shown, in which display panel a supplementary electrode 4 with a thickness of 3 nm is formed above the second electrode 33 of the red light-emitting device 3. Since the second electrode 33 of the red light-emitting device 301 is thicker, the microcavity effect of the red light-emitting device 301 is enhanced, so that the luminance decay of the red light-emitting device 301 is accelerated (as shown by the dotted line in FIG. 3), and further, the curves of luminance decay with the view angle of the red, green and blue light-emitting devices 301, 302 and 303 tend to be consistent, thereby improving the angular color shift of the display panel for white light.

In some embodiments, referring to FIG. 1c, another structural cross-sectional view taken along line AA′ of FIG. 1a is shown. In FIG. 1c, the pixel driving circuit in the substrate 1 is not shown; the supplementary electrode 4 is located on the second electrode 33 of the green light-emitting device 302; and the supplementary electrode mutual repulsion layer 5 is located on the second electrodes 33 of the red and blue light-emitting devices 301, 303.

In some embodiments, referring to FIG. 1d, yet another structural cross-sectional view taken along line AA′ of FIG. 1a is shown. In FIG. 1d, the pixel driving circuit in the substrate 1 is not shown; the supplementary electrode 4 is located on the second electrode 33 of the blue light-emitting device 303; and the supplementary electrode mutual repulsion layer 5 is located on the second electrodes 33 of the red and green light-emitting devices 301, 302.

In some embodiments, referring to FIG. 1e, yet another structural cross-sectional view taken along line AA′ of FIG. 1a is shown. In FIG. 1e, the pixel driving circuit in the substrate 1 is not shown; the supplementary electrode 4 is located on the second electrodes 33 of the red and green light-emitting device 301, 302; and the supplementary electrode mutual repulsion layer 5 is located on the second electrode 33 of the blue light-emitting device 303.

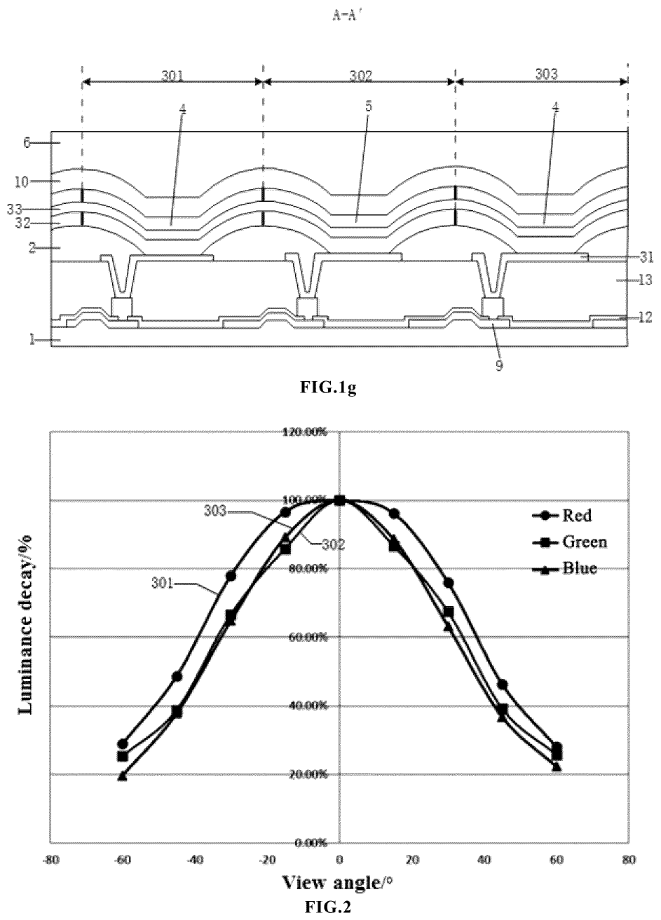

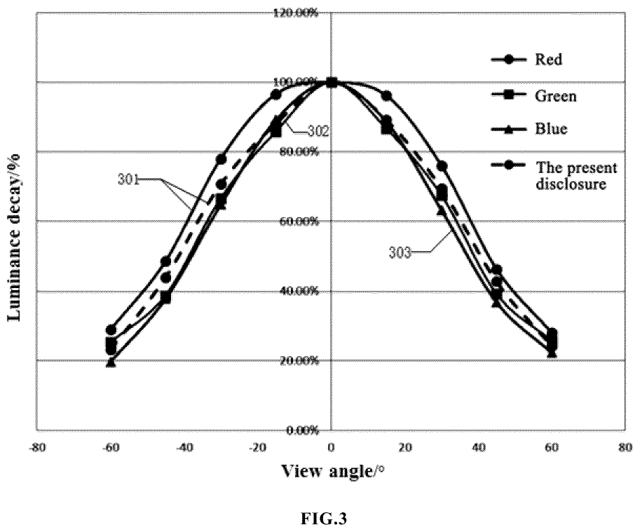

In some embodiments, referring to FIG. 4, another graph of luminance decay with the view angle of red, green and blue light-emitting devices in a display panel with no supplementary electrode is shown. As can be seen in the figure, the luminance decay with the view angle of the red and green light-emitting devices 301, 302 is slower than that of the blue light-emitting device 303. Referring to FIG. 5, a graph of luminance decay with the view angle of red, green and blue light-emitting devices in the display panel of FIG. 1e is shown, in which display panel a supplementary electrode 4 with a thickness of 4 nm is formed above the second electrodes 33 of the red and green light-emitting devices 301, 302. Since the second electrodes 33 of the red and green light-emitting devices 301, 302 are thickened, the microcavity effect of the red and green light-emitting devices 301, 302 is enhanced, so that the luminance decay of the red and green light-emitting devices 301, 302 is accelerated (as shown by the dotted line in FIG. 5), and further, the curves of luminance decay with the view angle of the red, green and blue light-emitting devices 301, 302 and 303 tend to be consistent, thereby improving the angular color shift of the display panel for white light.

In some embodiments, referring to FIG. 1f, yet another structural cross-sectional view taken along line AA′ of FIG. 1a is shown. In FIG. 1f, the pixel driving circuit in the substrate 1 is not shown; the supplementary electrode 4 is located on the second electrodes 33 of the blue and green light-emitting device 303, 302; and the supplementary electrode mutual repulsion layer 5 is located on the second electrode 33 of the red light-emitting device 301.

In some embodiments, referring to FIG. 1g, yet another structural cross-sectional view taken along line AA′ of FIG. 1a is shown. In FIG. 1g, the pixel driving circuit in the substrate 1 is not shown; the supplementary electrode 4 is located on the second electrodes 33 of the blue and red light-emitting device 303, 301; and the supplementary electrode mutual repulsion layer 5 is located on the second electrode 33 of the green light-emitting device 302.

In some embodiments, the first electrode 31 is made of an opaque metal or metal alloy material, such as an ITO/Ag/ITO stack; the second electrode 33 is made of a light-transmitting metal material; such as a magnesium or silver or any other light-transmitting metal material. The supplementary electrode 4 is made of a metal material including any one of Mg, Ag, Al, Li, K and Ca, or a metal alloy material including any one of MgₓAg₍₁₋ₓ₎, LiₓAl₍₁₋ₓ₎, LiₓCa₍₁₋ₓ₎ and LiₓAg₍₁₋ₓ₎. The supplementary electrode 4 is capable of transmitting light.

In some embodiments, the second electrode 33 has a thickness ranging from 1 nm to 20 nm; and the supplementary electrode 4 has a thickness ranging from 1 nm to 10 nm.

In some embodiments, the supplementary electrode mutual repulsion layer 5 is made of an amine, diamine, or triamine based material. The supplementary electrode mutual repulsion layer 5 is capable of transmitting light.

In some embodiments, the supplementary electrode mutual repulsion layer 5 is made of one any of —N,N′-diphenyl-N,N′-bis(9-phenyl-9H-carbazol-3-yl)biphenyl-4,4′-diamine; N-(biphenyl-4-yl)-9,9-dimethyl-N-(4-(9-phenyl-9H-carbazol-3-yl)phenyl)-9H-fluoren-2-amine; 4,4′,4″-tris(3-methylphenylphenylamino)triphenylamine; N,N′-bis(1-naphthyl)-N,N′-diphenyl[1,1′-biphenyl]-4,4′-diamine, or 4,4′-bis[N-(3-methylphenyl)-N-phenylamino]biphenyl; or N4,N4′-diphenyl-N4,N4′-bis(9-phenyl-9H-carbazol-3-yl)diphenyl-4,4′-diamine′N(diphe nyl-4-yl) 9,9-dimethyl-N-(4 (9-phenyl-9H-carbazol-3-yl)phenyl)-9H-fluoren-2-amine.

In some embodiments, referring to FIGS. 1b to 1g, the display panel further includes a light extraction layer 10 on a side of the supplementary electrode 4 and the supplementary electrode mutual repulsion layer 5 away from the substrate 1, and on a side of the encapsulation layer 6 close to the substrate 1. An orthographic projection of the light extraction layer 10 on the substrate 1 covers at least orthographic projections of the light-emitting devices 3 on the substrate 1.

In some embodiments, the orthographic projection of the light extraction layer 10 on the substrate 1 covers the entire substrate 1.

In some embodiments, the light extraction layer 10 has a refractive index of 1.8 or more at a wavelength of 530 nm, and an extinction coefficient of 0.01 or less at a wavelength of 450 nm to 780 nm. With the light extraction layer 10, the light extraction efficiency can be well increased.

In some embodiments, the light extraction layer 10 is made of a material including any one of N,N′-bis(1-naphthyl)-N,N′-diphenyl-1,1′-biphenyl-4-4′-diamine; a triphenyldiamine derivative; N,N′-diphenyl-N,N′-bis(4′-(N,N-bis(1-naphthyl)-amido)-4-biphenyl)-benzidine; 1,3,5-tris(N-3-methylphenyl-N-phenylamino)benzene; or copper phthalocyanine.

In some embodiments, the light extraction layer 10 has a thickness ranging from 60 nm to 100 nm.

In some embodiments, a side surface of the pixel defining layer 2, formed between two adjacent openings and away from the substrate 1, forms an arc surface that protrudes towards a side away from the substrate 1; and light-emitting functional layers 32 of the two adjacent light-emitting devices 3 extend onto the arc surface and meet each other; and second electrodes 33 of the two adjacent light-emitting devices 3 extend onto the arc surface and meet each other. The two adjacent light-emitting devices 3 have different colors.

In some embodiments, the second electrodes of the two adjacent light-emitting devices are spaced apart from each other (not shown).

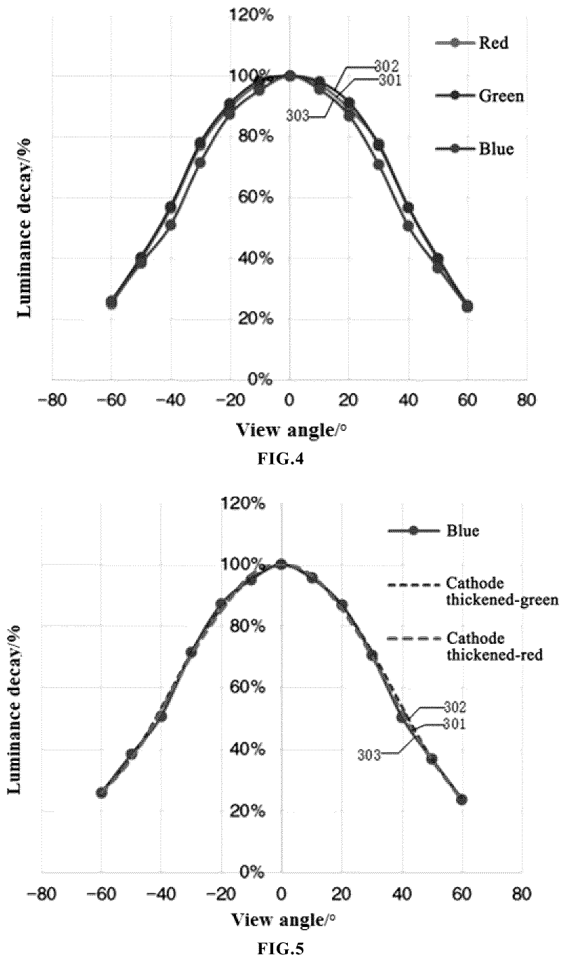

In some embodiments, referring to FIG. 6, yet another structural cross-sectional view taken along line AA′ of FIG. 1a is shown, in which light-emitting functional layers 32 of two adjacent light-emitting devices 3 extend onto the arc surface and are arranged in a lapped manner.

In some embodiments, referring to FIG. 6, a lapped area of the light-emitting functional layers 32 has a cross section perpendicular to the substrate 1 with a length A, and the opening has a cross section perpendicular to the substrate 1 with a length B; where A/B is less than 5%. The cross section of the lapped area of the light-emitting functional layers 32 perpendicular to the substrate 1 is parallel to the cross section of the opening perpendicular to the substrate 1. The length of the cross section of the lapped area of the light-emitting functional layers 32 perpendicular to the substrate 1 and the length of the cross section of the opening perpendicular to the substrate 1 are parallel to the substrate 1.

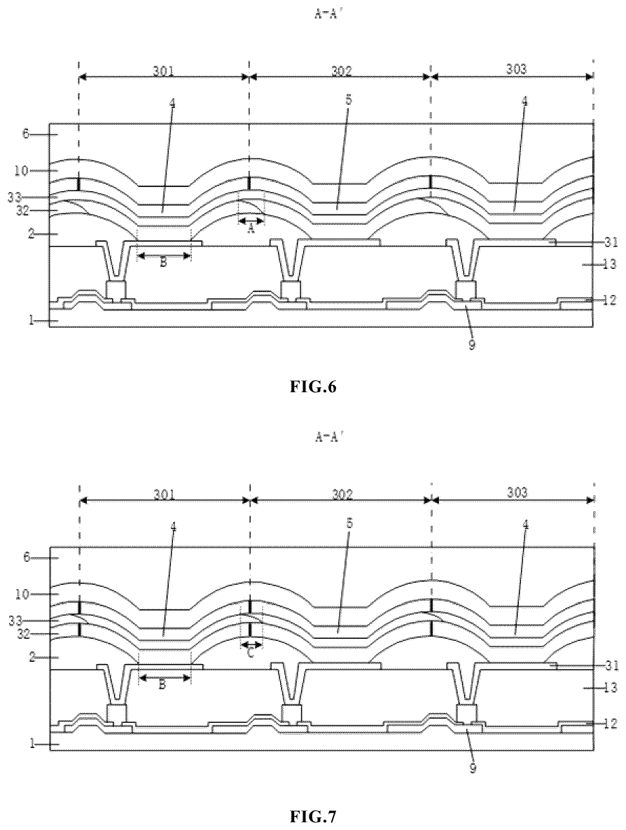

In some embodiments, referring to FIG. 7, yet another structural cross-sectional view taken along line AA′ of FIG. 1a is shown, in which second electrodes 33 of two adjacent light-emitting devices 3 extend onto the arc surface and are arranged in a lapped manner.

In some embodiments, a lapped area of the second electrodes 33 has a cross section perpendicular to the substrate 1 with a length C, where C/B is less than 5%. The cross section of the lapped area of the second electrodes 33 perpendicular to the substrate 1 is parallel to the cross section of the opening perpendicular to the substrate 1. The length of the cross section of the lapped area of the second electrodes 33 perpendicular to the substrate 1 and the length of the cross section of the opening perpendicular to the substrate 1 are parallel to the substrate 1.

In some embodiments, C≠A. It should be noted that the sizes of A, B and C in FIGS. 6 and 7 are merely schematic representations, and does not represent the actual sizes of A, B and C.

In some embodiments, C>A.

In some embodiments, the light-emitting functional layer 32 includes a hole injection layer, a hole transport layer, an electron blocking layer, a light-emitting layer, a hole blocking layer, an electron transport layer and an electron injection layer, which are sequentially arranged in a superimposed manner in a direction away from the substrate 1. The light-emitting layer is made of an organic electroluminescent material or a quantum dot light-emitting material. Namely, the light-emitting device 3 is an organic electroluminescent device or a quantum dot light-emitting device.

In some embodiments, the encapsulation layer 6 includes a first inorganic layer, an organic layer and a second inorganic layer sequentially arranged in a superimposed manner. The first inorganic layer and the second inorganic layer may be made of a silicon nitride, silicon oxide or silicon oxynitride material; and the organic layer may be made of an organic resin material. The encapsulation layer 6 can well prevent external water and oxygen from intruding into the inside of the light-emitting device 3.

An embodiment of the present disclosure further provides a display panel, including a substrate, and a pixel defining layer on the substrate, in which a plurality of openings are formed; a plurality of light-emitting devices of different colors on the substrate, the light-emitting devices being located in the openings. Each of the light-emitting devices includes a first electrode, a light-emitting functional layer and a second electrode sequentially superimposed away from the substrate. The display panel further includes: a supplementary electrode on a side of the second electrode away from the substrate, where an orthographic projection of the supplementary electrode on the substrate covers orthographic projections of second electrodes of the light-emitting devices of certain colors on the substrate; a supplementary electrode mutual repulsion layer on a side of the second electrode away from the substrate, where an orthographic projection of the supplementary electrode mutual repulsion layer on the substrate is complementary in pattern with the orthographic projection of the supplementary electrode on the substrate; and an encapsulation layer on a side of the supplementary electrode and the supplementary electrode mutual repulsion layer away from the substrate, and configured to encapsulate the light-emitting devices.

In an embodiment of the present disclosure, An orthographic projection of the second electrode on the substrate covers an orthographic projection of an effective light-emitting area of the light-emitting device on the substrate. With the orthographic projection of the supplementary electrode on the substrate covers orthographic projections of second electrodes of the light-emitting devices of certain colors on the substrate, the second electrodes of different colors of light-emitting devices differ in thickness, so that the optical resonant cavities (microcavities) formed between the first electrodes and the second electrodes of different colors of light-emitting devices also differ. The thicker the second electrode is, the stronger the microcavity effect of the light-emitting device is, and the faster the luminance of the light-emitting device decays with changes of the view angle. The luminance decay curve of a single color of light-emitting device is optimized by means of different strengths of the microcavity effect, so that the luminance decay curves of different colors of light-emitting devices tend to be the same, and thus the angular color shift of the display panel is improved.

An embodiment of the present disclosure further provides a display panel, including a substrate, and a pixel defining layer, in which a plurality of openings are formed, on the substrate; and a plurality of light-emitting devices of different colors on the substrate, the light-emitting devices being located in the openings. Each of the light-emitting devices includes a first electrode, a light-emitting functional layer and a second electrode sequentially superimposed away from the substrate. The display panel further includes: a supplementary electrode on a side of the second electrode away from the substrate, where an orthographic projection of the supplementary electrode on the substrate covers orthographic projections of first electrodes of the light-emitting devices of certain colors on the substrate; a supplementary electrode mutual repulsion layer on a side of the second electrode away from the substrate, where an orthographic projection of the supplementary electrode mutual repulsion layer on the substrate is complementary in pattern with the orthographic projection of the supplementary electrode on the substrate; and an encapsulation layer on a side of the supplementary electrode and the supplementary electrode mutual repulsion layer away from the substrate, and configured to encapsulate the light-emitting devices.

In an embodiment of the present disclosure, an orthographic projection of the first electrode on the substrate covers an orthographic projection of an effective light-emitting area of the light-emitting device on the substrate. With the orthographic projection of the supplementary electrode on the substrate covering orthographic projections of first electrodes of the light-emitting devices of certain colors on the substrate, the second electrodes of different colors of light-emitting devices differ in thickness, so that the optical resonant cavities (microcavities) formed between the first electrodes and the second electrodes of different colors of light-emitting devices also differ. The thicker the second electrode is, the stronger the microcavity effect of the light-emitting device is, and the faster the luminance of the light-emitting device decays with changes of the view angle. The luminance decay curve of a single color of light-emitting device is optimized by means of different strengths of the microcavity effect, so that the luminance decay curves of different colors of light-emitting devices tend to be the same, and thus the angular color shift of the display panel is improved.

Based on the above structure of the display panel, an embodiment of the present disclosure further provides a method of manufacturing the display panel, including the following steps S01 to S07. At step S01: preparing a substrate.

This step includes preparing a pixel driving circuit on a cleaned substrate, including preparing a transistor and a capacitor by a conventional patterning process.

At step S02: preparing a first electrode of a light-emitting device on the substrate.

In this step, a first electrode is prepared by a patterning process or an evaporation process.

At step S03: preparing a pixel defining layer and openings therein on the substrate after the above steps are completed.

At step S04: sequentially preparing a light-emitting functional layer and a second electrode on the substrate after the above steps are completed.

In this step, preparing the light-emitting functional layer includes sequentially preparing a hole injection layer, a hole transport layer, an electron blocking layer, a light-emitting layer, a hole blocking layer, an electron transport layer and an electron injection layer. The second electrode is prepared by an evaporation process.

At step S05: preparing a supplementary electrode mutual repulsion layer on the substrate after the above steps are completed.

In this step, the supplementary electrode mutual repulsion layer is prepared by an evaporation, printing or sputtering process. Specifically, a mask plate with a pattern of the supplementary electrode mutual repulsion layer is subjected to evaporation or sputtering to form the supplementary electrode mutual repulsion layer, or a supplementary electrode mutual repulsion layer film is firstly formed by a sputtering process, and then the pattern of the supplementary electrode mutual repulsion layer is formed by processes such as exposure, development, etching and the like.

At step S06: preparing a supplementary electrode on the substrate after the above steps are completed.

In this step, the supplementary electrode is prepared by an evaporation process. Specifically, a mask plate with a pattern of the supplementary electrode is subjected to evaporation to form the supplementary electrode.

At step S07: preparing an encapsulation layer on the substrate after the above steps are completed.

In some embodiments, after preparing the supplementary electrode and before preparing the encapsulation layer, the method further includes: preparing a light extraction layer by an evaporation, printing or sputtering process. For example, a mask plate with a pattern of the light extraction layer is subjected to evaporation or sputtering to form the light extraction layer.

An embodiment of the present disclosure further provides a display apparatus including the display panel according to any of the above embodiments.

By adopting the display panel according to any of the above embodiments, the luminance decay curve of a single color of light-emitting device can be optimized by means of different strengths of the microcavity effect, so that the luminance decay curves of different colors of light-emitting devices tend to be the same, and thus the angular color shift of the display apparatus is improved.

The display apparatus provided by the embodiment of the present disclosure may be any product or component with a display function, such as an OLED panel, an OLED television, an OLED billboard, a QLED panel, a QLED television, a QLED billboard, a monitor, a mobile phone, a navigator, or the like.

It will be understood that the above embodiments are merely exemplary embodiments adopted to illustrate the principles of the present disclosure, and the present disclosure is not limited thereto. It will be apparent to one of ordinary skill in the art that various modifications and improvements can be made without departing from the spirit and essense of the present disclosure, and such modifications and improvements are also considered to be within the protection scope of the present disclosure.

1. A display panel, comprising: a substrate;
a plurality of light-emitting devices of different colors on the substrate; wherein each of the plurality of light-emitting devices comprises a first electrode, a light-emitting functional layer, and a second electrode sequentially superimposed away from the substrate;
a supplementary electrode on a side of the second electrode away from the substrate, wherein an orthographic projection of the supplementary electrode on the substrate covers orthographic projections of light-emitting functional layers and/or second electrodes and/or first electrodes of the light-emitting devices of certain colors on the substrate;
a supplementary electrode mutual repulsion layer on a side of the second electrode away from the substrate, wherein an orthographic projection of the supplementary electrode mutual repulsion layer on the substrate is complementary in pattern with the orthographic projection of the supplementary electrode on the substrate; and
an encapsulation layer on a side of the supplementary electrode and the supplementary electrode mutual repulsion layer away from the substrate, and configured to encapsulate the light-emitting devices.

2. The display panel according to claim 1, wherein the plurality of light-emitting devices comprise red, green, and blue light-emitting devices,
the supplementary electrode is in contact with and connected to the second electrode; and
the supplementary electrode mutual repulsion layer is in contact with the second electrode.

3. The display panel according to claim 2, wherein the supplementary electrode is located on the second electrode of the red light-emitting device; and
the supplementary electrode mutual repulsion layer is located on the second electrodes of the green and blue light-emitting devices,
or, wherein the supplementary electrode is located on the second electrode of the green light-emitting device; and
the supplementary electrode mutual repulsion layer is located on the second electrodes of the red and blue light-emitting devices,
or, wherein the supplementary electrode is located on the second electrode of the blue light-emitting device; and
the supplementary electrode mutual repulsion layer is located on the second electrodes of the red and green light-emitting devices,
or, wherein the supplementary electrode is located on the second electrodes of the red and green light-emitting devices; and
the supplementary electrode mutual repulsion layer is located on the second electrode of the blue light-emitting device,
or, wherein the supplementary electrode is located on the second electrodes of the blue and green light-emitting devices; and
the supplementary electrode mutual repulsion layer is located on the second electrode of the red light-emitting device,
or, wherein the supplementary electrode is located on the second electrodes of the blue and red light-emitting devices; and
the supplementary electrode mutual repulsion layer is located on the second electrode of the green light-emitting device.

4-8. (canceled)

9. The display panel according to claim 2, wherein the second electrode is made of a light-transmitting metal material; and
the supplementary electrode is made of a metal material comprising any one of Mg, Ag, Al, Li, K and Ca, or a metal alloy material comprising any one of MgₓAg₍₁₋ₓ₎, LiₓAl₍₁₋ₓ₎, LiₓCa₍₁₋ₓ₎ and LiₓAg₍₁₋ₓ₎.

10. The display panel according to claim 9, wherein the second electrode has a thickness ranging from 1 nm to 20 nm; and
the supplementary electrode has a thickness ranging from 1 nm to 10 nm.

11. The display panel according to claim 9, wherein the supplementary electrode mutual repulsion layer is made of an amine, diamine, or triamine based material.

12. The display panel according to claim 11, wherein the supplementary electrode mutual repulsion layer is made of any one of —N,N′-diphenyl-N,N′-bis(9-phenyl-9H-carbazol-3-yl)biphenyl-4,4′-diamine; N-(biphenyl-4-yl)-9,9-dimethyl-N-(4-(9-phenyl-9H-carbazol-3-yl)phenyl)-9H-fluoren-2-amine; 4,4′,4″-tris(3-methylphenylphenylamino)triphenylamine; N,N′-bis(1-naphthyl)-N,N′-diphenyl[1,1′-biphenyl]-4,4′-diamine, or 4,4′-bis[N-(3-methylphenyl)-N-phenylamino]biphenyl; or N4,N4′-diphenyl-N4,N4′-bis(9-phenyl-9H-carbazol-3-yl)diphenyl-4,4′-diamine′N (diphenyl-4-yl)9,9-dimethyl-N-(4(9-phenyl-9H-carbazol-3-yl)phenyl)-9H-fluoren-2-amine.

13. The display panel according to claim 2, further comprising a light extraction layer on a side of the supplementary electrode and the supplementary electrode mutual repulsion layer away from the substrate, and on a side of the encapsulation layer close to the substrate; wherein
an orthographic projection of the light extraction layer on the substrate covers orthographic projections of at least the plurality of light-emitting devices on the substrate.

14. The display panel according to claim 13, wherein the light extraction layer has a refractive index of 1.8 or more at a wavelength of 530 nm, and an extinction coefficient of 0.01 or less at a wavelength of 450 nm to 780 nm.

15. The display panel according to claim 14, wherein the light extraction layer is made of a material comprising any one of N,N′-bis(1-naphthyl)-N,N′-diphenyl-1,1′-biphenyl-4-4′-diamine; a triphenyldiamine derivative; N,N′-diphenyl-N,N′-bis(4′-(N,N-bis(1-naphthyl)-amido)-4-biphenyl)-benzidine; 1,3,5-tris(N-3-methylphenyl-N-phenylamino)benzene; or copper phthalocyanine.

16. The display panel according to claim 13, wherein the light extraction layer has a thickness ranging from 60 nm to 100 nm.

17. The display panel according to claim 1, further comprising a pixel defining layer on the substrate, wherein a plurality of openings are formed in the pixel defining layer;
each of the plurality of light-emitting devices comprises a portion in a corresponding one of the plurality of openings;
a side surface of the pixel defining layer, formed between two adjacent ones of the plurality of openings and away from the substrate, forms an arc surface that protrudes towards a side away from the substrate; and
the two adjacent light-emitting devices have different colors.

18. The display panel according to claim 17, wherein light-emitting functional layers of the two adjacent light-emitting devices extend onto the arc surface and meet each other; and
second electrodes of the two adjacent light-emitting devices extend onto the arc surface, and meet each other or are spaced apart from each other.

19. The display panel according to claim 17, wherein light-emitting functional layers of the two adjacent light-emitting devices extend onto the arc surface and are arranged in a lapped manner.

20. The display panel according to claim 19, wherein a lapped area of the light-emitting functional layers has a cross section perpendicular to the substrate with a length A,
each opening has a cross section perpendicular to the substrate with a length B; where
A/B is less than 5%;
the cross section of the lapped area of the light-emitting functional layers perpendicular to the substrate is parallel to the cross section of the opening perpendicular to the substrate; and
the length of the cross section of the lapped area of the light-emitting functional layers perpendicular to the substrate, and the length of the cross section of the opening perpendicular to the substrate, are parallel to the substrate.

21. The display panel according to claim 20, wherein second electrodes of the two adjacent light-emitting devices extend onto the arc surface and are arranged in a lapped manner.

22. The display panel according to claim 21, wherein a lapped area of the second electrodes has a cross section perpendicular to the substrate with a length C, where
C/B is less than 5%;
the cross section of the lapped area of the second electrodes perpendicular to the substrate is parallel to the cross section of the opening perpendicular to the substrate; and
the length of the cross section of the lapped area of the second electrodes perpendicular to the substrate, and the length of the cross section of the opening perpendicular to the substrate, are parallel to the substrate.

23-25. (canceled)

26. The display panel according to claim 15, wherein the light-emitting functional layer comprises a hole injection layer, a hole transport layer, an electron blocking layer, a light-emitting layer, a hole blocking layer, an electron transport layer and an electron injection layer,
the hole injection layer, the hole transport layer, the electron blocking layer, the light-emitting layer, the hole blocking layer, the electron transport layer and the electron injection layer are sequentially superimposed along a direction away from the substrate; and
the light-emitting layer is made of an organic electroluminescent material or a quantum dot light-emitting material.

27. A display apparatus, comprising the display panel according to claim 1.

28. A method of manufacturing a display panel, comprising:
preparing a substrate;
preparing a first electrode of a light-emitting device on the substrate;
preparing a pixel defining layer and openings therein on the substrate;
sequentially preparing a light-emitting functional layer and a second electrode on the substrate;
preparing a supplementary electrode mutual repulsion layer on the substrate;
preparing a supplementary electrode on the substrate; and
preparing an encapsulation layer on the substrate.

29-30. (canceled)
